(19) United States
(12) Patent Application Publication
(10) Pub. No.: US 2002/0151147 A1
(43) Pub. Date: Oct. 17, 2002

(54) Manufacturing of a lateral bipolar transistor

(76) Inventor: Lothar Strobel, Hamburg (DE)

Correspondence Address: U.S. Philips Corporation, 580 White Plains Road, Tarrytown, NY, 10591, US

(21) Appl. No.: 10/114,494

(22) Filed: Apr. 2, 2002

(30) Foreign Application Priority Data
Apr. 7, 2001 (DE) 10117558.2

(51) Int. Cl. H01L 21/00; H01L 21/84; H01L 21/337; H01L 21/8238; H01L 21/8249; H01L 21/331

(52) U.S. Cl. 438/311; 438/149; 438/189; 438/202; 438/234; 438/336

(57) ABSTRACT

A lateral bipolar transistor with a doped zone of a small lateral width can be obtained by means of a method for manufacturing a lateral bipolar transistor with a collector region and a base region in a SOI wafer slice with an insulating layer, a silicon layer over the insulating layer, with a protective coating of oxide over the silicon layer, with trenches through the protective layer and the silicon layer as far as the insulating layer with substantially lateral walls, which are bounded by substantially lateral faces of the protective coating and the silicon layer, by implanting dopants in the silicon layer, in which the implantation takes place on one of the substantially lateral faces of the silicon layer.

It is preferable for the base zone to be formed by implantation at an angle of inclination of 30 to 60° between the normal to the wafer slice and the ion-beam direction of the ion implantation on one of the substantially lateral faces of the silicon layer.

The invention relates to the manufacturing of a lateral bipolar transistor in SOI technology.

Because of the increasing demand for portable, battery-operated instruments which have a low current consumption for applications in telecommunications, lateral bipolar transistors have become the focal point of technological activities. Lateral bipolar transistors are particularly suitable for front-end applications with a low current consumption in a medium-frequency range.

The article by R. Dekker, W. T. A. v.d. Einden, H. G. R. Maas, “An Ultra Low Power Lateral Bipolar Polysilicon Emitter Technology on SOI”, 1993 IEEE, IEDM 93-75, 4.4.1 presents a method for producing lateral bipolar transistors of this kind in which the base and the emitter are produced by means of conventional ion implantation. In order to expose the active base face, the silicon must be exposed on the base side following the ion implantation by means of anisotropic etching. However this production method entails various disadvantages. No end-point signal is possible for the etching operation, step heights of up to 0.6 μm give rise to difficulties in anisotropic etching, and the polyemitter lies on an etched flank.

It is therefore the object of the invention to indicate a method of manufacturing a lateral bipolar transistor in SOI technology in which the indicated disadvantages are avoided.

The object is solved according to the invention by a method of manufacturing a lateral bipolar transistor with a collector region and a base region in a SOI wafer slice with an insulating layer, a silicon layer over the insulating layer, with a protective coating of oxide over the silicon layer, with trenches through the protective layer and the silicon layer as far as the insulating layer with substantially lateral walls, which are bounded by substantially lateral faces of the protective coating and the silicon layer, by implanting dopants in the silicon layer, in which the implantation takes place on one of the substantially lateral faces of the silicon layer.

It is particularly preferable, within the scope of the invention, for the base region to be formed by implantation on one of the substantially lateral faces of the silicon layer.

The mode of operation of a lateral bipolar transistor requires a narrow base region, so that the charge carriers can pass out of the emitter space through the boundary layer between the emitter region and the base region and through the base region and thus be able to influence the processes at the boundary layer between the base region and the collector region, thereby controlling the flow of current between the base and the collector.

In the known methods the base region is produced by means of conventional ion implantation, lateral outdiffusion of the dopant and subsequent etching away of a part of the silicon layer. The deposition and etching methods which are used in this case are subject to variances and therefore influence the lateral width of the doped zone.

It is also preferable for the implantation to take place at an angle of inclination of 30 to 60° between the normal to the wafer slice and the ion-beam direction of the ion implantation.

The invention will be further described with reference to examples of embodiments shown in the drawings, to which, however, the invention is not restricted.

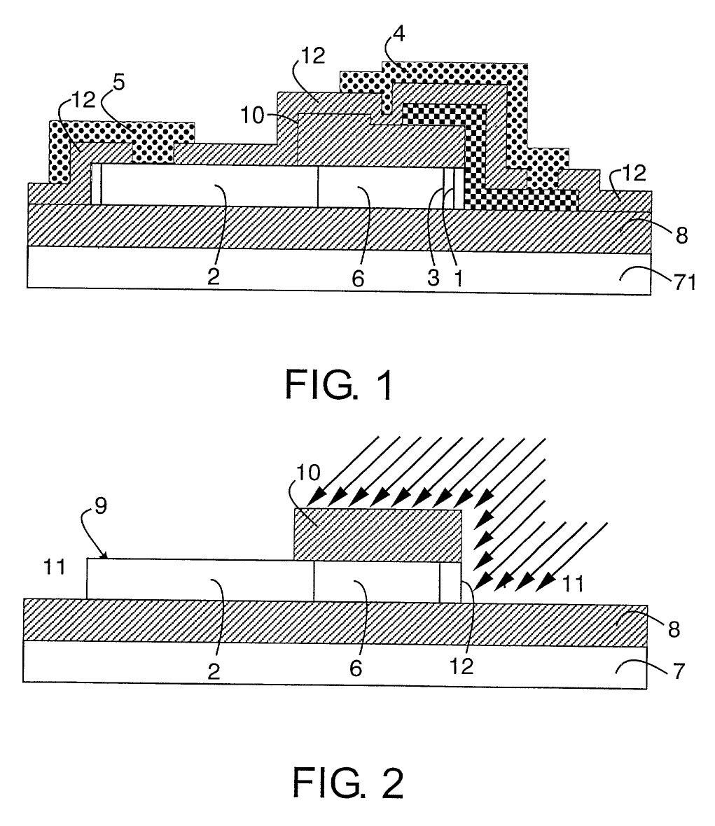

FIG. 1 represents a cross section through a lateral bipolar transistor with a polysilicon emitter

FIG. 2 represents the method step according to the invention of the oblique ion implantation of the base.

A bipolar transistor comprises three differently doped n- or p-regions in a semiconductor crystal (in most cases a silicon crystal) with two p-n junctions lying in between. The two outer areas of the same conduction type are called the emitter region 1 and the collector region 2, and the central area, which is at most several μm thick, is called the base region 3, while the electrodes which are attached thereto are called the emitter 4, the base and the collector 5. The minority carrier current through the base is assisted by an (incorporated) drift region 6 between the collector and the base, this region being produced by a non-homogeneous impurity distribution between the collector and the base.

A lateral bipolar transistor is a bipolar transistor in which—in contrast to the planar transistor—the emitter, the base and the collector are disposed horizontally (laterally). The injection current from the emitter to the collector therefore flows in the lateral direction along the surface.

Lateral bipolar transistors in SOI technology are produced in thin semiconducting layers on insulating substrates. Regions for the emitter and the collector are produced by locally limited re-doping in an area which is also of a relatively large vertical extent and is doped for the base conduction type.

According to a preferred embodiment of the invention, a lateral bipolar transistor with a polysilicon emitter is produced in SOI technology.

The structure which is represented in FIG. 2 constitutes the starting point for the method according to the invention.

The substrate material which is used here is a silicon wafer 7, which is covered by an oxide layer 8 of the thickness dₒₓ₂. This oxide layer is followed by the silicon layer 9 of the thickness d_{S1}, over which the oxide block Wₑₚᵢ 10 of the thickness dₒₓ₁ lies in the area of the drift region. A layer structure of this kind can be obtained in various ways. A conventional method lies in depositing polycrystalline silicon on a previously oxidized silicon substrate with subsequent recrystallization. Relatively low defect densities can as a rule be achieved by bonding two previously oxidized semiconductor slices and subsequently etching away a semiconductor layer down to the desired film thickness (BESOI method). The SIMOX method may also be used for slight film thicknesses. Oxygen atoms are in this case implanted in a single-crystal wafer. These accumulate in a layer below the semiconductor surface. A layer Of SiO₂ forms below a thin semiconducting film in a subsequent temperature step.

An npn or a pnp transistor with one of the following doping sequences can be produced according to the invention in the silicon layer: n⁺pn⁻n⁺ (standard sequence), n⁺npn⁻nⁿ⁺ (n buffer layer between the base and the emitter to reduce breakdown, leakage rates and capacitances), n⁺npn⁻nn⁺ (n buffer layer between the base and the collector).

The silicon layer d_{Si} may be between 20 nm and 2 μm thick, while the doping level of this layer is between 10¹⁵ cm⁻³ and 10¹⁸ cm⁻³, with donors or acceptors being added according to the type of transistor.

The areas which are intended for the subsequent transistor areas are firstly defined by photolithography. The vertical dimensions of the transistor are automatically obtained through the used thickness of the original silicon layer on the SOI substrate.

The silicon layer is provided with a basic doping. The parts of the silicon layer which lie outside of the area which is intended for the transistor are etched away, so that a trench 11 is produced. The trench, which extends as far as the insulating layer, forms the complete dielectric insulation of the transistor towards the outside.

Once the transistor has been insulated, a 400 nm thick TEOS layer is deposited and structured. An oxide block 10 is formed as a result, the width of which block determines the width of the drift region.

The collector region is afterwards defined by a mask, which is produced by photolithography, and produced by implantation with dopant. The dopant may, for example, be phosphorus in the form of PH₃, which is implanted at a dose of 5.0 10²⁰ cm⁻³. An annealing or diffusion step is also an option.

The base region 3 is then formed by implantation on the substantially lateral face of the silicon layer 12. The dopant may, for example, be boron in the form of BH₃ or BF₃. The dose of the implantation for the base region is set such that the doping reaches values of 10¹⁷ cm³.

As shown in FIG. 2, the implantation is preferably carried out at an angle of inclination of 30 to 60° between the normal to the wafer slice and the ion-beam direction of the ion implantation. It must be borne in mind that the effective implantation energy is reduced by the oblique implantation.

The slice may at the same time also be rotated in wobbled fashion, continuously or in each case through 90°.

It is optionally also possible to carry out an annealing or diffusion step here. After the base region is diffused out vertically and not laterally, it can be produced highly accurately with a very narrow lateral dimension of, for example, 40 nm.

The polysilicon emitter 4 is then deposited, implanted, structured by photolithography and diffused.

The dielectric layer 12 is afterwards deposited, the contact holes are etched and the contacts formed.

In the described embodiment of the invention the base is in each case laterally drawn out, i.e. the base region extends in the form of a strip perpendicularly to the drawing plane of the figures and ends in a highly doped base terminal region, which serves as a base terminal and is accordingly contacted. This contacting may take place directly through metal or indirectly through a contact layer consisting of polysilicon.

1. A method of manufacturing of a lateral bipolar transistor with a collector region and a base region in a SOI wafer slice with an insulating layer, a silicon layer over the insulating layer, with a protective coating of oxide over the silicon layer, with trenches through the protective layer and the silicon layer as far as the insulating layer with substantially lateral walls, which are bounded by substantially lateral faces of the protective coating and the silicon layer, by implanting dopants in the silicon layer, characterized in that the implantation takes place on one of the substantially lateral faces of the silicon layer.

2. A method as claimed in claim 1, characterized in that the base region is formed by implantation on one of the substantially lateral faces of the silicon layer.

3. A method as claimed in claim 1, characterized in that the implantation takes place at an angle of inclination of 30 to 60° between the normal to the wafer slice and the ion-beam direction of the ion implantation.
